(19) United States
(12) Patent Application Publication
(10) Pub. No.: US 2007/0119813 A1
(43) Pub. Date: May 31, 2007

(54) Gate patterning method for semiconductor processing

(75) Inventors: Francis Gabriel Celii, Dallas, TX (US); Kenneth Allen Hewes, Richardson, TX (US); Sandra Zheng, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/287,776

(22) Filed: Nov. 28, 2005

(51) Int. Cl. H01L 21/461; B44C 1/22; H01L 21/302; C23F 1/00

(52) U.S. Cl. 216/41; 216/79; 257/315; 438/706

(57) ABSTRACT

A method of patterning a polysilicon feature includes forming a hard mask layer over a polysilicon layer, wherein the hard mask layer includes a silicon rich silicon oxynitride layer, and a silicon oxynitride layer or bottom anti-reflective coating (BARC) layer overlying the silicon rich silicon oxynitride layer. The method further includes forming a photoresist layer over the hard mask layer, selectively exposing the photoresist layer with 193 nm ultraviolet radiation, and developing the exposed photoresist, thereby defining a photoresist feature. The hard mask layer is then patterned using the photoresist feature as an etch mask, and the polysilicon layer is patterned using the patterned hard mask as an etch mask.

### FIELD OF INVENTION

The present invention relates generally to semiconductor processing and more particularly to a hard mask structure and method of patterning gate or other features in the manufacture of transistor devices.

### BACKGROUND OF THE INVENTION

A conventional MOS transistor generally includes a semiconductor substrate, such as silicon, having a source, a drain, and a channel positioned between the source and drain. A gate stack composed of a conductive material (a gate conductor), a gate dielectric layer (a gate oxide), and sidewall spacers, is typically located above the channel. The gate dielectric is typically located directly above the channel, while the gate conductor, generally comprised of polycrystalline silicon (polysilicon) material, is located above the gate oxide. The sidewall spacers protect the sidewalls of the gate conductor.

The semiconductor industry continuously attempts to manufacture integrated circuits having geometric features that are decreasing in size, and these attempts in turn lead to the need for photolithographic techniques using shorter wavelengths in the mid and deep ultraviolet (DUV) spectrum to achieve fine features. In the process of defining very fine patterns, optical effects are often experienced which lead to distortion of images in the photoresist that are directly responsible for line width variations, and which in turn can compromise device performance.

Many of the optical effects that lead to distortion can be attributed to reflectivity of the underlying layers of materials, such as polysilicon and metals, which can produce spatial variations in the radiation intensity in the photoresist during exposure thereof, and in turn result in non-uniform line width development. Radiation can also scatter from the substrate and photoresist interfaces into areas where exposure is not intended, again resulting in line width variation.

As the wavelength of exposure sources is shortened to bring improved resolution by minimizing diffraction limitations, the difficulty in controlling reflections is increased. In an attempt to circumvent the reflection problems, a number of anti-reflective coatings (ARC) have been developed and are interposed between the substrate (or layer of interest) and the photoresist, but such solutions sometimes suffer varying shortcomings.

To further complicate the problem, photoresists for short wavelength exposure sources to deep ultraviolet (DUV) light are necessarily very thin, and either do not withstand, or are undercut during the subsequent etch process of the underlying layer, resulting in further deterioration of the line resolution. Clean-up and removal of both the resist, and the anti-reflective coating can present additional problems in the manufacturing process of sub-micron features.

As lithography techniques progress, for example, by moving to the 193 nm (nanometer) wavelength of an ArF excimer laser light, a need exists for a method to form sub-micron integrated circuit patterns which overlay varying topographies, and often highly reflective substrate or underlying layer materials. In particular, defining precise, sub-micron features in relatively thick doped and undoped polysilicon over gate oxide presents a significant challenge to the industry. A single layer, inorganic anti-reflective coating of silicon oxynitride (Siₓ,O_{y}N_{z}) has been used in the industry as a hard mask to pattern the polysilicon gate, and while it has advantages, its selectivity to oxide, and slow removal rate with phosphoric acid post etch clean-up has an adverse effect on the polysilicon line definition, and may result in damage to active areas. Alternately, a bi-layer hard mask of silicon oxynitride over doped silicon oxide has been proposed. However, the optical properties of the oxide have a narrow process window, an undesirable feature for volume manufacturing, and further the process is complicated by the requirement of a special tool for removal.

Therefore, an anti-reflective hard mask coating for deep UV exposure in the 193 nm wavelength region which is compatible with polysilicon etch and clean-up processes, and which supports volume manufacturing requirements of sub-micron polysilicon features is clearly needed by the industry.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present invention is directed to a multi-layer hard mask structure and associated method, wherein an ARC (anti-reflective coating) bi-layer is employed that exhibits a tunable layer that is operable to substantially match the index of refraction (n) and extinction coefficient (k) with respect to the overlying photoresist layer, for example, to minimize reflection with 193 nm wavelength exposure. The bi-layer overlies a gate electrode layer (e.g., a polysilicon layer) that will ultimately become a gate structure, and operates as an ARC when an overlying photoresist is undergoing exposure, and is subsequently patterned to serve as an etch hard mask for patterning the gate electrode.

Preferably the ARC mask comprises a bottom layer of greater than 200 angstroms, and less than 800 angstroms of silicon rich oxynitride having an extinction coefficient (at 193 nm) of from about 0.4 to about 1.6, and a top layer of about 300 angstroms of silicon oxynitride having an extinction coefficient of about 0.1. The silicon rich oxynitride is in direct contact with an underlying gate electrode layer overlying a gate oxide, or other dielectric layer. An etch hard mask is formed from the ARC bi-layer by etching in selected areas unprotected by an overlying photoresist. The resist is removed, for example, by plasma ashing, and the exposed polysilicon etched along with the silicon oxynitride layer, leaving primarily the silicon rich oxynitride to be removed by a phosphoric acid or other type post polysilicon etch clean-up, which does not damage active moat and gate areas.

According to one aspect of the invention, a method of patterning a gate electrode feature is disclosed, and comprises forming a hard mask layer over the gate electrode layer. The hard mask layer comprises a bi-layer, wherein a first layer comprises a silicon rich silicon oxynitride layer directly overlying the gate electrode layer, and a silicon oxynitride layer or a bottom anti-reflective coating (BARC) layer directly overlying the silicon rich silicon oxynitride layer. A photoresist layer is formed over the hard mask layer, exposed to 193 nm ultraviolet radiation, and developed, thereby defining a photoresist feature. The photoresist feature is used to pattern at least the top layer of the hard mask, and the remaining hard mask, at least the silicon rich silicon oxynitride layer is employed as the etch mask to pattern the underlying gate electrode layer. The oxygen content within the silicon rich silicon oxynitride layer may be varied to selectively reduce the index of refraction (n) and the extinction coefficient (k) of the film, thereby advantageously facilitating improved matching of such optical parameters with respect to the overlying photoresist, thereby reducing reflections during exposure.

In accordance with another aspect of the invention, the oxygen content within the silicon rich silicon oxynitride layer is less than the oxygen content in the overlying portion of the hard mask layer, thereby making the silicon rich silicon oxynitride-more “soft” with respect to a subsequent wet clean after patterning the gate electrode layer. Consequently, the clean operation does less damage to the underlying gate electrode layer, thereby improving the pattern transfer reliability. Such feature substantially improves integration of the gate patterning process with the rest of the integrated circuit fabrication.

According to another aspect of the invention, a method of tuning the optical properties of a hard mask layer to reduce reflectance associated therewith is provided. The method comprises evaluating one or more optical properties associated associated with a photoresist to be employed in a photolithographic patterning process. The method further comprises determining an amount of oxygen to incorporate within a silicon rich silicon oxynitride film portion of a hard mask layer, wherein the determination substantially matches the optical properties of the hard mask layer with that of the photoresist, thereby reducing reflectance associated therewith during an exposure of the photoresist.

In according with still another aspect of the invention, evaluating the optical properties of the photoresist comprises evaluating one or more of a composition and a thickness of the photoresist. In addition, determining the amount of oxygen comprises selecting a feed gas flow rate of a feed gas containing oxygen for a silicon rich silicon oxynitride layer deposition recipe to achieve the desired index of refraction (n) and the extinction coefficient (k) of the film.

According to yet another aspect of the invention, a hard mask structure for use in patterning a gate electrode is disclosed. The structure includes a gate structure overlying a semiconductor body, wherein the gate structure comprises a gate dielectric layer and a gate electrode layer overlying the gate dielectric layer. A hard mask bi-layer overlies the gate structure, and comprises a silicon rich silicon oxynitride layer, and a silicon oxynitride layer or a bottom anti-reflective coating (BARC) layer overlying the silicon rich silicon oxynitride layer. In one embodiment of the invention the silicon rich silicon oxynitride film comprises a stoichiometry of Si_{X}O_{Y}N_{Z}, wherein X>0.75 and Y>0.

In still another aspect of the invention a gate electrode feature is disclosed, wherein the gate electrode feature is formed by the process comprising forming a hard mask layer over a gate electrode layer, wherein the hard mask layer comprises a silicon rich silicon oxynitride layer, and a silicon oxynitride layer or bottom anti-reflective coating (BARC) layer overlying the silicon rich silicon oxynitride layer. A photoresist layer is formed over the hard mask layer, selectively exposed with 193 nm ultraviolet radiation, and developed to define a photoresist feature. The hard mask layer is then patterned using the photoresist feature as an etch mask, and the gate electrode is patterned using the patterned hard mask as an etch mask. The patterning of the gate electrode results in a substantial portion of the top layer of the bi-layer hard mask being removed. Subsequently, a clean operation is performed to remove a remaining portion of the bottom layer of the bi-layer hard mask.

In one embodiment of the invention, the bottom layer of the bi-layer hard mask has less than the oxygen content than the overlying portion of the hard mask bi-layer, wherein the oxygen content thereof causes the bottom portion of the hard mask to be relatively “soft” compared to the top hard mask layer with respect to the wet clean thereof. Consequently, the removal of the remaining hard mask is relatively easy, and results in reduced damage to the underlying gate electrode layer.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1 is a flow chart illustrating a method of patterning a gate electrode according to one example of the present invention;

FIGS. 2A-2G are fragmentary cross section diagrams illustrating various steps in patterning the gate electrode in accordance with the method of FIG. 1 according to another aspect of the invention;

FIG. 3 is a flow chart diagram illustrating a method of tuning optical properties of a hard mask layer for a given photoresist to reduce reflectance associated therewith according to another aspect of the present invention;

FIG. 4 is a chart illustrating the optical constant space associated with a silicon rich silicon nitride film;

FIG. 5 is a chart illustrating the optical constant space associated with a silicon rich silicon oxynitride film, and more particularly illustrating how increasing an oxygen content associated therewith provides an additional degree of freedom in tuning optical properties associated with the film; and

FIG. 6 is a graph illustrating how an increase in an amount of oxygen associated with a silicon rich silicon oxynitride film reduces both the index of refraction and the extinction coefficient associated with the film, thereby providing a mechanism for tuning the optical properties of the film.

### DETAILED DESCRIPTION OF THE INVENTION

One or more implementations of the present invention will now be described with reference to the attached drawings, wherein like reference numerals are used to refer to like elements throughout, and wherein the illustrated structures are not necessarily drawn to scale.

According to the invention, a method is provided for fabricating a semiconductor device having narrow, sharply defined gate electrode features (e.g., polysilicon) by using deep UV exposure, such as 193 nanometers (nm). The invention includes forming and employing a bi-layer hard mask, wherein a bottom layer of the hard mask comprises a silicon rich silicon oxynitride layer. The hard mask layer is sandwiched between the gate electrode layer and the photoresist layer, and serves both as an anti-reflective coating having highly selective optical properties, and as a hard mask that is stable during the etch of the gate electrode and the subsequent clean-up processes.

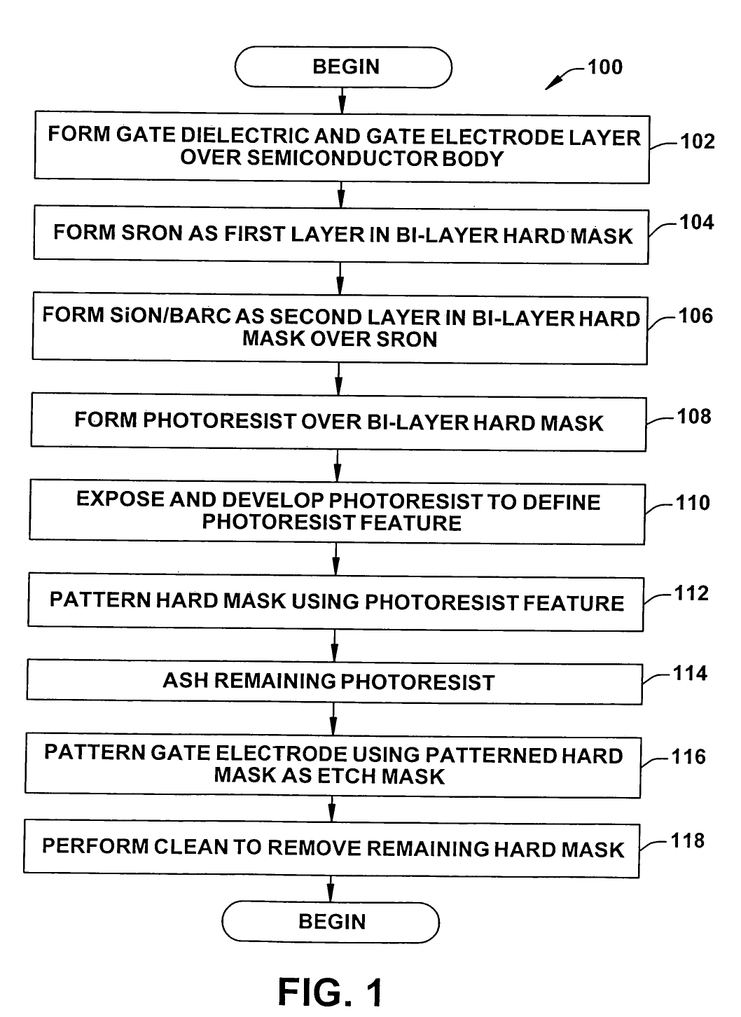

FIG. 1 is directed to a flow chart illustrating a method 100 of patterning an underlying layer such as a gate electrode according to one aspect of the present invention. While the method 100 example and other methods of the invention are illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the fabrication of devices which are illustrated and described herein as well as in association with other devices and structures not illustrated.

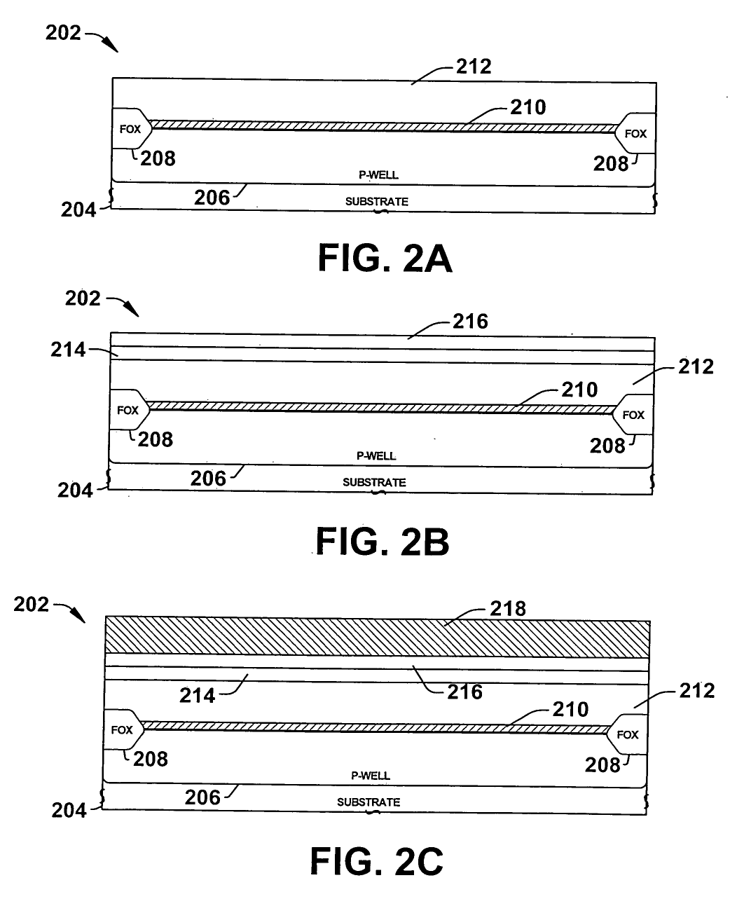

The method 100 begins with the formation of a gate dielectric layer and a gate electrode layer over a semiconductor body at 102. For example, as illustrated in FIG. 2A, a semiconductor body may comprise a substrate 204 having a doped well region therein, for example, a p-well 206 within which an NMOS type device may be fabricated (or an active region in an silicon-on-insulator (SOI) device, etc.). In one example, the active areas (or moat regions) are defined and isolated from one another from isolation regions such as field oxide regions 208 (FOX), shallow trench isolation regions (STI), or other type isolation structures. On the active area a gate dielectric 210 is formed, for example, an oxide formed by thermal oxidation. Alternatively, the gate dielectric may be a high-K dielectric material, and be formed for example, by a chemical vapor deposition (CVD), or other process. Further referencing FIG. 2A, a gate electrode layer 212 is formed over the gate dielectric layer 210. The gate electrode layer 212 may be any suitable electrode material, for example, a polysilicon or metal material, as may be appreciated, and may be formed by an suitable deposition process, such as CVD. As will be further appreciated infra, the gate dielectric layer 210 and gate electrode layer 212 together will form a gate structure, upon appropriate patterning thereof.

Returning to FIGS. 1 and 2B, the method continues at 104, wherein a first portion of a bi-layer hard mask is formed over the gate electrode layer. In accordance with the present invention, the first portion of the bi-layer hard mask comprises a silicon rich silicon oxynitride layer 214, and is deposited by a CVD process. Generally, such a layer 214 may be formed, in one example, with the following flow gases: SiH₄, NH₃, He and N₂O, however, other process recipes may be employed and are contemplated as falling within the scope of the present invention. A second portion of the bi-layer hard mask is then formed over the silicon rich silicon oxynitride layer (SRON) 214 at 106 of FIG. 1, wherein the second layer 216 comprises either a silicon oxynitride layer or a bottom anti-reflective coating (BARC) layer. In accordance with the present invention, a BARC comprises an organic layer that serves to minimize reflection associated therewith when under exposure. One example of a BARC material is AR19, manufactured by Shipley Company, L.L.C., a subsidiary of Rohm and Haas.

In one aspect of the invention, the dual anti-reflective thin film hardmask layer of materials (e.g., a bi-layer) includes the silicon rich oxynitride (SRON) layer 214 overlying the polysilicon 212, and the silicon oxynitride (SiON) layer 216 over the SRON. One advantageous aspect of the present invention is the inorganic bi-layer film having specific anti-reflective properties that improves a depth of focus of the lithographic process. In addition, the bi-layer film exhibits a large process window, and operates as a hard mask which is able to withstand the subsequent etch process without deterioration of either the polysilicon line width, or the underlying oxide, moat, or other active areas.

Silicon oxynitride (Si_{X}O_{Y}N_{Z}) is an advantageous anti-reflective coating for deep UV resist exposures largely because of the low index of refraction or “n” value. Such films have been manufactured having an index of refraction in the range of 1.8 to 1.9, for example, and having extinction coefficients or “k” values which can be varied from, for example, 0.32 to 0.86. However, the removal of these materials is difficult without resulting in damage to the moat and the gate line width, thus making the single Si_{X}O_{Y}N_{Z} film unsatisfactory for manufacturing some types of semiconductor devices.

The bi-layer anti-reflective coating films 214 and 216 are formed over the wafer, for example, in a parallel plate PECVD (plasma enhanced chemical vapor deposition) reactor, such as a Centura Mainframe, DxZ process chamber as supplied by Applied Materials. The deposition processes for the bi-layer hardmask 214, 216 using the reactor includes, for example, a process temperature of 350 C., a pressure of 6.2 Torr, and an RF power of 60 Watts for SRON 214, and an RF power of 120 Watts for the SiON 216. For the silicon rich silicon oxynitride 214 deposition, in one example, SiH₄ is introduced at 50 sccm, NH₃ at 50 sccm, He at 1000 sccm, and N₂O at 20 sccm. Following the SRON 214 deposition, a silicon oxynitride 216 (SiON) is formed in the same chamber by, for example, introducing SiH₄ at 63 sccm, N₂O at 187 sccm, and He at 1900 sccm.

The following are example flow rates for the formation of the SRON film 214 and the resultant stoichiometries associated therewith that may be employed in accordance with the present invention. In the table below, the RF is in Watts, Space is in mils, the gas flow rates are in sccm, and the deposition times are in seconds.

TABLE 1

| | | | | | | | Dep. | |
|---|---|---|---|---|---|---|---|---|
| Run | RF | Space | SiH4 | NH3 | He | N20 | Time | Film |
| 1 | 60 | 300 | 50 | 50 | 1000 | 20 | 116.7 | SiO_{0.166}N_{0.486} |
| 2 | 60 | 300 | 50 | 50 | 1000 | 100 | 83.4 | SiO_{0.529}N_{0.518} |
| 3 | 60 | 600 | 50 | 290 | 3000 | 50 | 127.9 | SiO_{0.238}N |
| 4 | 60 | 300 | 250 | 290 | 3000 | 130 | 96.3 | SiO_{0.183}N_{0.480} |
| 5 | 60 | 300 | 250 | 290 | 3000 | 160 | 89.8 | SiO_{0.225}N_{0.4} |

A photoresist layer is then formed over the bi-layer hard mask at 108 of FIG. 1, as illustrated in FIG. 2C, wherein the photoresist layer is indicated at reference numeral 218. The thin layer of photoresist 218 is formed over the anti-reflective thin hardmask film 214, 216. The photoresist 218 has a thickness, for example, in the range of about 2000 to about 3000 angstroms and is, in one example, a positive acting deep UV resist, such as PAR 707 or 710 from Sumitomo Chemicals. In one example, the very thin photoresist 218 is kept thin in order to improve depth of focus for the deep UV exposure, as well as to allow easy of resist removal.

The method 100 then continues at 110, wherein the photoresist is selectively exposed to ultraviolet radiation (e.g., 193 nm wavelength) through, for example, a mask (not shown), resulting in a patterned photoresist mask 220, as illustrated in FIG. 2D.

The method 100 of FIG. 1 then continues, in one example, at 112 by patterning the hardmask composed of layers 214 and 216, as illustrated in FIG. 2E, wherein layers 214 and 216 are patterned to form a bi-layer hardmask 221 composed of a layer 222 (e.g., the silicon oxynitride or BARC) overlying the silicon rich silicon oxynitride 224. The layers 214 and 216 are patterned using, for example, a dry etch such as in a commercially available plasma etch reactor using CF₄ and O₂. An example etch recipe that would etch the bi-layer hardmask uses a CF₄ flow rate of 90 sccm, CHF₃ flow of 10 sccm and Ar flow of 100 sccm at 4 mTorr, with plasma source power of 360 W and plasma bias of 60 W.

The remaining photoresist 218 left on top of the patterned bi-layer hardmask 221 is then removed at 114 of FIG. 1, for example, by an ashing operation or other removal process. For example, the photoresist 218 is removed by an oxygen ash step, which may be accomplished in the same reactor as the etching of the bi-layer hardmask 221. In one process example, the photoresist is rapidly removed by an ash process using an O₂ flow rate of 100 sccm and N₂ flow of 200 sccm at 10 mTorr. In one process example, the photoresist is rapidly removed by an ash process using an O₂ flow rate of 100 sccm and N₂ flow of 50 sccm at 50 mTorr, with plasma source power of 600 W and plasma bias of 100 W.

The gate electrode layer 212 is then patterned using the bi-layer hardmask 221 as the etch mask at 116 of FIG. 1, as illustrated in FIG. 2F. The polysilicon etch is accomplished in a commercially available plasma etcher using an etchant such as CF₄, or CF₄ combined with CHF₃. The specific etch process parameters are dependent on: the etch equipment, the polysilicon thickness, the polysilicon doping, and the desired post-etch polysilicon profile (e.g., straight or notched; sidewall angle; foot).

As can be seen in FIG. 2F, the top layer 222 of the bi-layer hardmask 221 (i.e., the silicon oxynitride or BARC layer) is substantially, or in some cases, completely etched during the gate patterning process, wherein the top layer 222 serves as a sacrificial type layer during the patterning. A substantial portion of the bottom layer 224, however, remains and serves to define the resultant gate electrode structure 226, as illustrated.

Fabrication of the polysilicon feature is completed by removing the silicon rich silicon nitride 214 using conventional hot phosphoric acid post polysilicon etch clean-up processing. The completed polysilicon feature 226 is illustrated in FIG. 2G. Subsequent processing may then proceed, such as formation of source/drain regions, metallization, etc.

In accordance with one advantageous aspect of the present invention, the top layer 216 of the bi-layer hardmask 221 is formed with more oxygen therein than in the underlying SRON layer 214. In the above example, the top SiON layer 216 is more “hard” than the lower layer with respect to the post-etch cleaning thereof, which is used to remove such layers after the gate electrode is patterned. Since the top layer 216 is exposed during a substantial amount of the gate electrode patterning, the increased oxygen makes the layer more selective with respect to the polysilicon etch and thus although the top layer 216 does experience a substantial amount of etching thereof, thus serving as a sacrificial layer, the top layer 216 can be maintained as thin as possible. After the patterning of the gate electrode 226, the top portion of the bi-layer hardmask 221 is substantially or entirely removed. Consequently, the post-etch clean-up the wet rinse is performed primarily or entirely on the underlying SRON layer 214.

The inventor of the present invention has advantageously appreciated a heretofore unappreciated integration advantage of having the silicon rich silicon oxynitride (SRON) layer 214 formed under the silicon oxynitride (SiON) layer 216. By maintaining less oxygen in the underlying SRON layer 214, the layer is more soft with respect to the wet etchant (the hot phosphoric acid rinse) used to remove such layer after the gate electrode 226 is defined. Accordingly, it has been found that removal of the SROn layer 214 with the hot phosphoric acid rinse can be performed with a higher dilution level, or for a shorter time, or both, than compared with a wet removal of the top portion 216 of the bi-layer 221. Consequently, the bi-layer hardmask 221 of the present invention results in less damage to the formed gate electrode and the exposed moat or active regions (if exposed in the process) during post-etch clean-up than in alternative type solutions where such layers in the bi-layer hardmask 221 may be switched.

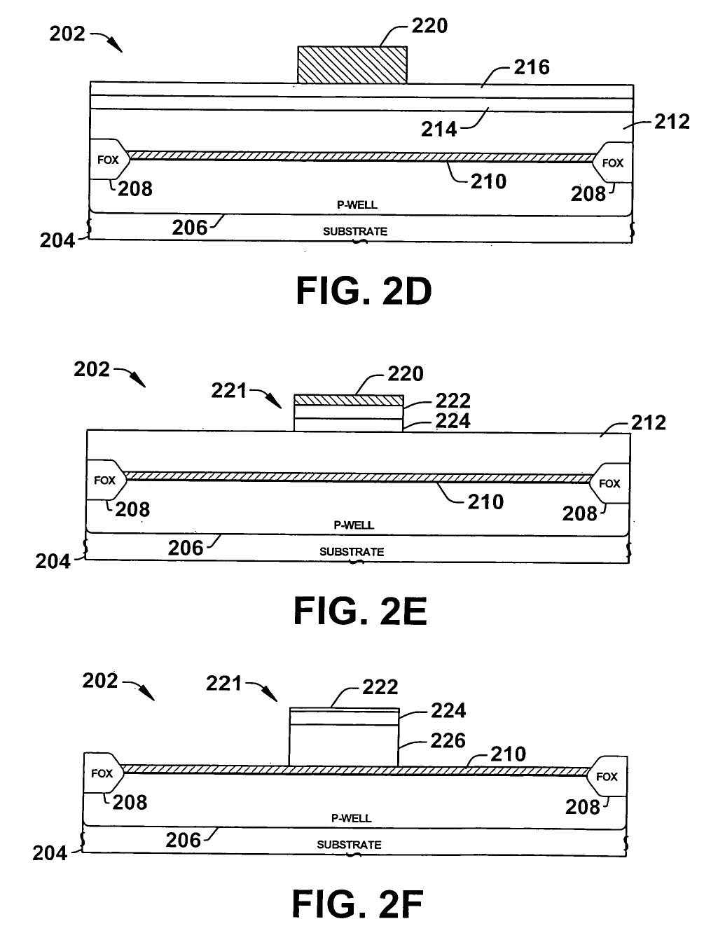

According to another aspect of the present invention, a method of ascertaining a hardmask composition associated with the patterning of a gate electrode is provided herein, as illustrated in the flow chart of FIG. 3. The method 300 includes evaluating the properties associated with the photoresist at 302. In one example, such evaluation may include evaluating the composition of the photoresist that will be employed in the subsequent patterning of the subsequent layers, for example, the photoresist layer 218 of FIG. 2C. In another example, such evaluation at 302 may include evaluating a thickness of the photoresist layer. In yet another example, the exposure wavelength employed in the subsequent exposure of the photoresist may be evaluated, and all such options, or their combination, are contemplated by the present invention.

The method 300 of FIG. 3 continues at 304 with a determination of an amount of oxygen to incorporate into a silicon rich silicon oxynitride (SRON) film portion of a hardmask in order to match optical properties thereof with that of the evaluated photoresist at 302. In one example, the amount of oxygen in the SRON film is determined to minimize the reflectance of the exposure light during the patterning of the overlying photoresist. In one example, the hardmask is a bi-layer hardmask structure such as bi-layer film 221 of FIGS. 2C and 2D, wherein the top layer 216 is a silicon oxynitride film (SiON), and the underlying layer 214 is the silicon rich silicon oxynitride film (SRON). In one example, in addition to the oxygen content of the SRON being tailored for desired optical properties, the oxygen content of the overlying SiON film is selected to be greater than that of the underlying SRON film, for the integration advantages highlighted above.

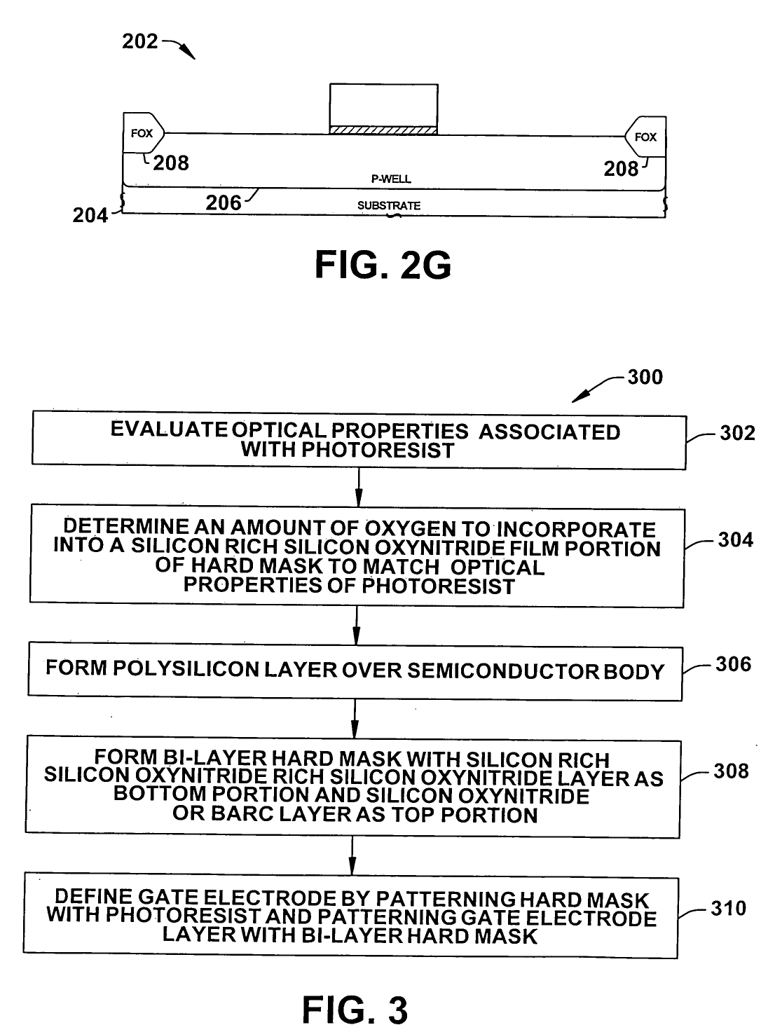

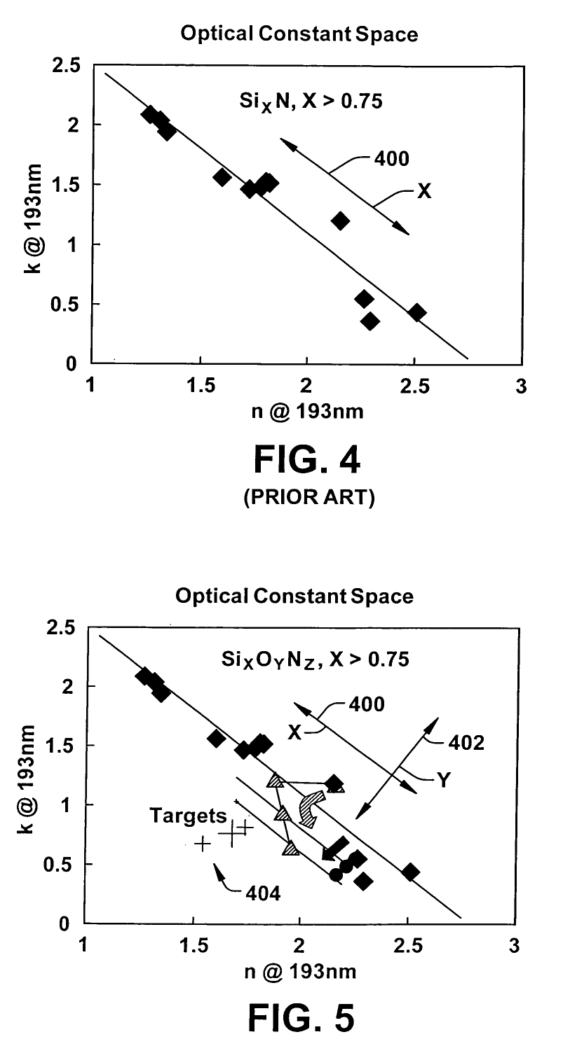

As can be seen in FIGS. 4 and 5, the silicon rich silicon oxynitride (SRON) film of the present invention provides unique tuning advantages in tuning the optical coefficients “n” and “k”. As illustrated in prior art FIG. 4, a graph is provided that illustrates a silicon rich nitride film (SiₓN, wherein X>0.75). As can be seen in the graph, as the amount of silicon is varied in the film, the optical coefficients “n” and “k” do vary generally along the axis 400, wherein an increase in “n” results in a decrease in “k” and vice-versa. However, according to the present invention, it was appreciated that by adding oxygen, a silicon rich silicon oxynitride film (Si_{X}O_{Y}N_{Z}, wherein X>0.75) provides improved design freedom in matching optical characteristics thereof with that of an overlying photoresist by moving the optical coefficients along a second axis 402 that is generally perpendicular to the first axis 400. In the above manner, it can be seen in FIG. 5 that by adjusting the amount of oxygen therein, the resultant film can be tuned to mitigate the heretofore trade-off between “n” and “k”, and instead provide the ability to reduce both “n” and “k” concurrently (e.g., in the area or zone 404 illustrated in FIG. 5). In the above manner, improved optical properties are provided when employing such a film as an anti-reflective layer and a hardmask layer in patterning the gate electrode.

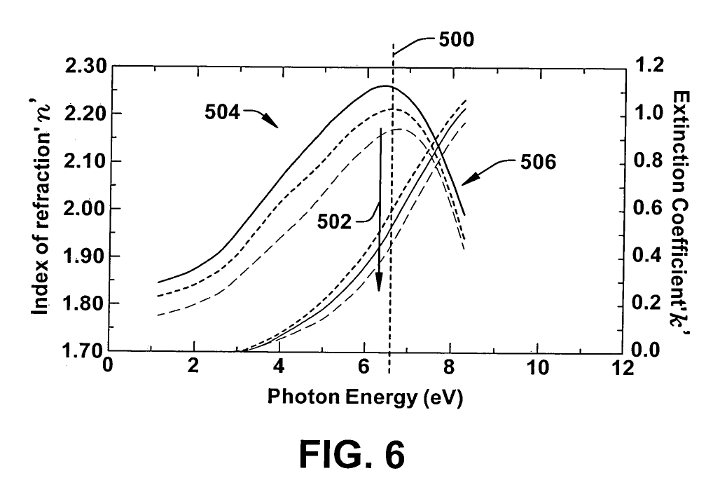

FIG. 6 is another graph that helps illustrate the improved tenability of the optical coefficients of the film according to the present invention. The dotted line 500 corresponds to an exposure wavelength of 193 nm, and the arrow 502 illustrates an increasing N2O gas flow rate that may be used to incorporate additional oxygen in the SRON film. The top three curves 504 highlight a lowering of the “n” coefficient from approximately 2.25 to approximately 2.15 for increasing amounts of oxygen. The bottom three curves 506 highlight a lowering of the coefficient “k” for increasing amounts of oxygen from approximately 0.5 to approximately 0.4. Thus in the example of FIG. 6, both “n” and “k” are concurrently reduced in contrast to the trade-off of the prior art film highlighted in prior art FIG. 4.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method of patterning a polysilicon feature, comprising:
forming a hard mask layer over a polysilicon layer, the hard mask layer comprising a silicon rich silicon oxynitride layer, and a silicon oxynitride layer or bottom anti-reflective coating (BARC) layer overlying the silicon rich silicon oxynitride layer;
forming a photoresist layer over the hard mask layer;
selectively exposing the photoresist layer with 193 nm ultraviolet radiation;
developing the exposed photoresist, thereby defining a photoresist feature;
patterning the hard mask layer using the photoresist feature as an etch mask; and
patterning the polysilicon layer using the patterned hard mask as an etch mask.

2. The method of claim 1, wherein an amount of oxygen in the silicon oxynitride layer or the BARC layer is greater than in the silicon rich oxynitride layer.

3. The method of claim 1, wherein the silicon rich silicon oxynitride film comprises a stoichiometry of Si_{X}O_{Y}N_{Z}, wherein X>0.75 and Y>0.

4. The method of claim 3, wherein forming silicon rich silicon oxynitride layer portion of the hard mask layer comprises:
depositing the silicon rich silicon oxynitride layer using a chemical vapor deposition process, wherein the chemical vapor deposition process includes an oxygen containing feed gas.

5. The method of claim 4, wherein the oxygen containing feed gas comprises N₂O.

6. The method of claim 4, wherein the chemical vapor deposition process comprises providing SiH₄, NH₃, He along with the oxygen containing feed gas.

7. The method of claim 6, wherein the oxygen containing feed gas comprises N₂O.

8. A method of tuning optical properties of a hark mask layer to reduce reflectance associated therewith, comprising:
evaluating optical properties associated with a photoresist; and
determining an amount of oxygen to incorporate into a silicon rich silicon oxynitride film portion of the hard mask layer to thereby substantially match optical properties of the hard mask layer with the optical properties of the photoresist, and thereby reducing reflectance associated therewith.

9. The method of claim 8, wherein evaluating the optical properties of the photoresist comprises evaluating one or more of a composition and a thickness of the photoresist to be employed in patterning an underlying layer.

10. The method of claim 8, wherein determining the amount of oxygen comprises selecting a feed gas flow containing oxygen for a silicon rich silicon oxynitride deposition process recipe to achieve a desired optical property associated therewith that is related to the photoresist.

11. The method of claim 8, wherein the hard mask layer comprises the silicon rich silicon oxynitride layer and a silicon oxynitride layer formed thereover, wherein an amount of oxygen in the silicon oxynitride layer is greater than in the silicon rich oxynitride layer.

12. The method of claim 8, further comprising:
forming a polysilicon layer;
forming the hard mask layer comprising the silicon rich silicon oxynitride film over the polysilicon layer;
forming the photoresist over the hard mask layer;
patterning the polysilicon layer using the photoresist and the hard mask layer, respectively.

13. The method of claim 12, wherein the hard mask layer further comprises a silicon oxynitride film overlying the silicon rich silicon oxynitride film.

14. The method of claim 12, wherein patterning the polysilicon layer using the photoresist comprises:
selectively exposing the photoresist with 193 nm ultraviolet radiation; and
developing the exposed photoresist, thereby resulting in removal of the exposed photoresist and defining a remaining photoresist portion overlying the hard mask layer and the polysilicon.

15. The method of claim 14, wherein patterning the polysilicon layer further comprises:
patterning the hard mask layer using the remaining photoresist portion as an etch mask; and
patterning the polysilicon layer using the patterned hard mask layer as an etch mask.

16. A hard mask structure for use in patterning a gate electrode, comprising:
a gate structure overlying a semiconductor body, the gate structure comprising a gate dielectric layer and a gate electrode layer overlying the gate dielectric layer; and
a hard mask bi-layer overlying the gate structure, the hardmask bi-layer comprising:
a silicon rich silicon oxynitride layer; and
a silicon oxynitride layer or a bottom anti-reflective coating (BARC) layer overlying the silicon rich silicon oxynitride layer.

17. The hard mask structure of claim 16, wherein an amount of oxygen in the silicon oxynitride layer or the BARC layer is greater than in the silicon rich oxynitride layer.

18. The hard mask structure of claim 16, wherein the silicon rich silicon oxynitride film comprises a stoichiometry of Si_{X}O_{Y}N_{Z}, wherein X>0.75 and Y>0.

19. A gate electrode feature, formed by the process comprising:
forming a hard mask layer over a gate electrode layer, the hard mask layer comprising a silicon rich silicon oxynitride layer, and a silicon oxynitride layer or bottom anti-reflective coating (BARC) layer overlying the silicon rich silicon oxynitride layer;
forming a photoresist layer over the hard mask layer;
selectively exposing the photoresist layer with 193 nm ultraviolet radiation;
developing the exposed photoresist, thereby defining a photoresist feature;
patterning the hard mask layer using the photoresist feature as an etch mask; and
patterning the gate electrode layer using the patterned hard mask as an etch mask.

20. The hard mask structure of claim 19, wherein an amount of oxygen in the silicon oxynitride layer or the BARC layer is greater than in the silicon rich oxynitride layer.

21. The feature of claim 19, wherein the silicon rich silicon oxynitride film comprises a stoichiometry of Si_{X}O_{Y}N_{Z}, wherein X>0.75 and Y>0.

22. The feature of claim 21, wherein forming silicon rich silicon oxynitride layer portion of the hard mask layer comprises:
depositing the silicon rich silicon oxynitride layer using a chemical vapor deposition process, wherein the chemical vapor deposition process includes an oxygen containing feed gas.

23. The feature of claim 22, wherein the oxygen containing feed gas comprises N₂O.
